(19) United States
(12) Patent Application Publication
(10) Pub. No.: US 2026/0043140 A1
(43) Pub. Date: Feb. 12, 2026

(54) DECORATIVELY COATED POLYMER SUBSTRATES AND PROCESS FOR OBTAINING THE SAME

(71) Applicant: AGC GLASS EUROPE, Louvain-la-Neuve (BE)

(72) Inventors: Eric MICHEL, Gosselies (BE); Eric TIXHON, Gosselies (BE)

(21) Appl. No.: 19/101,161

(22) PCT Filed: Jul. 25, 2023
(86) PCT No.: PCT/EP2023/070643

§ 371 Date: Feb. 4, 2025

(30) Foreign Application Priority Data
Aug. 4, 2022 (EP) 22188895.1

(51) Int. Cl. C23C 16/503; C23C 16/40; H01J 37/32

(52) U.S. Cl. CPC C23C 16/503; C23C 16/401; H01J 37/32449; H01J 37/32596; H01J 2237/3321

(57) ABSTRACT

The present invention concerns a polymer substrate bearing a decorative coating comprising a protective toplayer of boron doped silicon oxide, wherein the boron doped silicon oxide comprises Si, O, B, H and OH groups and wherein the boron content is comprised between 4 and 12 atomic %. The present invention further comprises a process for depositing on a polymer substrate by linear hollow cathode type PECVD a boron doped silicon oxide layer comprising Si, O, B, H and OH groups and wherein the boron content is comprised between 4 and 12 atomic %.

### TECHNICAL FIELD

The present invention relates to a polymer substrate bearing a decorative coating comprising a boron doped silicon oxide protective toplayer. The present invention further concerns a plasma enhanced chemical vapor deposition method for depositing a decorative coating comprising a boron doped silicon oxide protective toplayer on a polymer substrate.

### BACKGROUND ART

Uncoated polymer substrates, such as for example of Acrylonitrile butadiene styrene (ABS) or polycarbonate (PC) possibly mixed with ABS, frequently have a dull appearance and are therefore frequently need to be provided with a coating to increase the amount of reflected light to make them aesthetically more pleasing.

In addition, such polymer substrates are frequently used in applications where they are exposed to mechanical wear, in particular scratching.

It is known to add lacquer layers on polymer substrates, both for mechanical protection and for aesthetical purposes. It was however found that the protection provided by these lacquer layers still needs to be improved at least regarding scratch resistance. Furthermore, such lacquer layers are thick, having thicknesses well above 1 μm, and require important quantities of chemicals in time consuming deposition processes.

Some polymer substrates are provided with a metal layer to give them the appearance of metallic parts. Such a coated polymer substrate may be used as a substitute for metal parts, in particular having a decorative function, in particular on vehicles. These metal layers also need protection from mechanical wear and chemical attack such as oxidation.

There is therefore a need in the art for layers that improve polymer substrates' resistance to chemical and/or mechanical degradation and that improve their aesthetic appearance.

### SUMMARY OF INVENTION

It is an objective of the present invention to make available polymer substrates that are mechanically durable, having good adhesion properties and being in particular resistant to abrasion, while at the same time providing a desirable aesthetical appearance.

Thus, the present invention concerns a polymer substrate bearing a coating comprising a protective toplayer of boron doped silicon oxide, wherein the boron doped silicon oxide comprises Si, O, B, and OH groups and wherein the boron content is comprised between 4 and 12 atomic %.

In certain embodiments of the present invention, the protective toplayer of boron doped silicon oxide is the only layer of the decorative coating.

In certain embodiments of the present invention, the decorative coating comprises one or more layers in between the substrate and the protective toplayer of boron doped silicon oxide.

It is another objective of the present invention to provide a fast and efficient method for the deposition on a polymer substrate of a coating comprising a boron doped silicon oxide protective toplayer, wherein the boron doped silicon oxide comprises Si, O, B, and OH groups and wherein the boron content is comprised between 4 and 12 atomic %.

In certain embodiments of the present invention, a process for the deposition on a polymer substrate of a protective boron doped silicon oxide layer comprising Si, O, B, and OH groups and wherein the boron content is comprised between 4 and 12 atomic %, comprises:
a. providing a polymer substrate,
b. providing a plasma source, of linear hollow-cathode type, which source has a length, comprising at least one pair of hollow-cathode plasma generating electrodes, and comprises at least one electrode pair connected to an AC, DC or pulsed DC generator power source, for the deposition of said protective layer on the substrate,
c. injecting a plasma generating reactive gas comprising oxygen in the plasma source's electrodes at a flow rate of between 125 and 750 sccm per linear meter of plasma source length;
d. applying an electrical power to the plasma source of between 10 and 50 kW per linear meter of plasma source length, and,
e. injecting a precursor gas at a flow rate of between 500 and 2500 sccm per linear meter of plasma source length, the precursor gas being injected into the plasma in at least between the electrodes of each electrode pair of the plasma source, depositing the protective layer on the polymer substrate by exposing the substrate to the plasma of the plasma source.

### BRIEF DESCRIPTION OF THE FIGURES

For a fuller understanding of the nature of the present invention, reference is made to the following detailed description taken in conjunction with the accompanying drawings in which:

FIGS. 1 to 3 illustrate different polymer substrates bearing decorative coatings comprising a protective toplayer of boron doped silicon oxide according to embodiments of the present invention.

FIG. 4 shows a transverse section of a hollow cathode type linear plasma source comprising one electrode pair for depositing the protective layer of the present invention.

FIG. 5 shows the deposition section of a hollow cathode type linear plasma source for the continuous deposition the protective layer of the present invention in relation to a substrate.

### DETAILED DESCRIPTION OF THE INVENTION

The inventors have surprisingly found that the protective toplayer of the present invention provides polymer substrates with improved aesthetical appearance by increasing their shininess, as determined by gloss measurements, and additionally provides good mechanical resistance in abrasion tests.

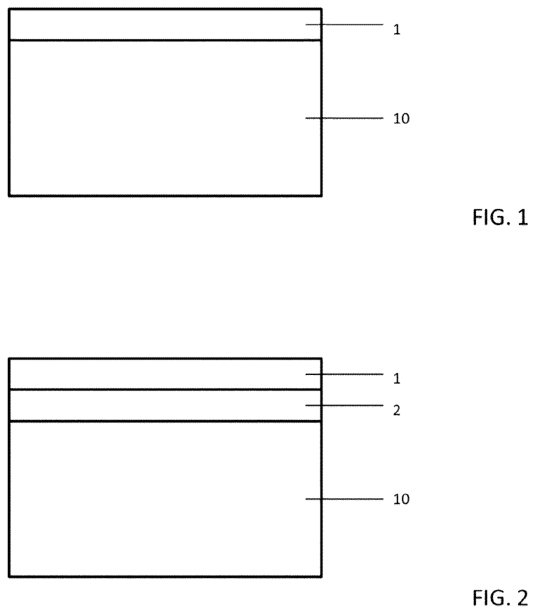

Preferably, the decorative coating does not comprise any organic adhesion layers, or polymeric basecoats. If present, the metal coating may be in direct contact with the substrate or else the protective toplayer may be in direct contact with the substrate. FIG. 1 shows a polymer substrate (10) wherein the protective toplayer (1) is in direct contact with the substrate. FIG. 2 shows a polymer substrate (10) wherein the metal coating (2) is in direct contact with the substrate and the protective toplayer (1) is in direct contact with the metal coating (2).

The polymer substrates of the present invention may be used as decorative elements in a wide variety of applications, on appliances, electronic devices, furniture, or building elements for example. Their enhanced durability makes them particularly well suited for use on vehicles, for example on cars. This latter application is particularly interesting when the substrate is polymer-based and to be used as a replacement of metallic parts that fulfil at least a decorative function.

The decorative coating on the polymer substrate may further comprise, between the substrate surface and the protective toplayer, a metal coating.

The metal coating may comprise one or more metal layers. The layers of the metal coating may have a thickness of up to 1 μm. Such metal coatings provide polymer substrates with a metallic look, allowing them to be used as replacements of metal parts. The protective toplayer protects the metal layer from scratches and chemical attack. Preferably, the one or more layers of the metal coating are deposited by magnetron sputtering.

Advantageously, the metal coating is in direct contact with the polymer substrate and/or the protective toplayer.

According to an embodiment of the present invention, the metal coating comprises comprise one or more layers comprising a material is selected among Ag, Cu, Al, Cr, Zr, Ti, Si, NiCr-alloys or NiCrW alloys.

In an advantageous embodiment of the present invention, the metal coating comprises two layers. Advantageously, a first adhesion metal layer of NiCr is in direct contact with the polymer substrate and in direct contact with a second layer of a metal chosen among Ag, Cu, Al, Cr, Zr, Ti, Si, or NiCrW alloys. The first layer may then provide improved adhesion between the second layer and the substrate.

The boron doped silicon oxide protective toplayer of the present invention comprises OH groups. The presence of OH groups is a feature that distinguishes these coatings from magnetron sputtered coatings, which do not provide the same level of protection. To the best of the inventors' knowledge, it may be at least partly due to this combination of OH groups and boron doping that the boron doped silicon oxide layer of the present invention has protective abilities. The presence of OH groups can be determined by Fourier Transform Infrared spectroscopy (FTIR) on an equivalent protective toplayer deposited on a silicon substrate. The presence of OH groups in the protective toplayer are detected by the presence of an absorption peak at a wavenumber of 3300 to 3500 cm⁻¹, corresponding to an —OH stretching vibration. Additional absorption peaks corresponding to Si—OH stretching vibrations may be visible between 900 and 1000 cm-1, these peaks may however overlap with the more intense peak of Si—O stretching vibrations.

In an embodiment of the present invention the FTIR absorbance peak area ratio A_{OH}/A_{SiOSi} of the —OH stretching vibrations (A_{OH}) and the Si—O—Si stretching vibrations (A_{SiOSi}) is comprised between 0.25 and 0.5. The absorption peak for —OH stretching vibrations appears at a wavenumber of 3300 to 3500 cm⁻¹, the absorption peak for Si—O—Si stretching vibrations appears at a wavenumber of 1080 to 1090 cm⁻¹.

In SiO₂ based coatings deposited by sputtering, some hydrogen may be unintentionally present in the gas phase, in the decorative coating however, the FTIR absorbance peak area ratio A_{OH}/A_{SiOSi} was found to be <0.05. Furthermore, SiO₂ based coatings deposited by sputtering generally comprise aluminum, as aluminum is added to silicon sputtering targets to increase its conductivity. The boron doped silicon oxide layers of the present invention may be free of aluminum.

The boron doped silicon oxide layers of the present invention were found to be amorphous and non-porous, as seen for example by transmission electron microscopy.

The boron doped silicon oxide layers of the present invention comprise or may essentially consist of silicon, boron, oxygen and hydrogen.

In any of the embodiments hereinabove, the boron doped silicon oxide layer may have a boron content from 4 to 12 at % of B. Within this doping range, the refractive index may remain very low, that is, comprised between 1.4 and 1.5 at a wavelength of 633 nm, in particular if the SiO₂ content by weight is at least 80%. At the same time, good chemical resistance of the multilayer coating is obtained and the haze level after thermal strengthening can be kept low and may in particular be kept at values below 0.3%.

The content of boron in the boron doped silicon oxide layer is preferably determined by x-ray photoelectron spectroscopy (XPS) or else by secondary ionization mass spectrometry (SIMS) using appropriate standards for a quantitative appreciation.

According to an embodiment of the present invention, boron doped silicon oxide protective toplayer may have a thickness of at least 80 nm to show a more noticeable improvement of durability. The thickness may be adapted over a wide range so as to adjust the optical properties of the final coated product. Thus, the thickness of the boron doped silicon oxide layer may be up to 400 nm, in particular up to 350 nm, more particularly up to 300 nm. Such high thicknesses are not suitable for magnetron sputtering deposition, due to the slow deposition rates of silicon oxide base coatings.

According to an embodiment of the present invention, the boron doped silicon oxide layers of the present invention may have an atomic ratio of O/Si comprised between 1.9 and 2.6. It was found that at lower boron doping levels the O/Si atomic ratio was lower.

According to an embodiment of the present invention, the boron doped silicon oxide coating of the present invention may, in particular, be free of carbon. Absence of carbon may be particularly interesting for reducing absorptance of the layer and may help reducing the number of defects that occur upon thermal strengthening of the coated products. The presence of carbon is a significant drawback of sol-gel coatings, in addition to the complications of integrating a sol gel coating process in a multilayer coating process.

For the purpose of the present invention, a layer is considered to be free of carbon when no carbon signal is detectable above signal noise for carbon of either x-ray fluorescence spectroscopy or secondary ion mass spectroscopy signals. It should be noted that surface contamination, in particular of carbon, that occurs naturally on coatings upon exposure to free air shall be ignored upon analysis.

The boron doped silicon oxide protective toplayer of any of the embodiments or combinations of embodiments hereinabove may advantageously be deposited using plasma enhanced chemical vapor deposition (PECVD), in particular using a linear plasma source, such as a hollow cathode plasma source. By operating under vacuum, PECVD can be easily integrated into a vacuum coating line, such as a magnetron sputtering line.

The invention relates, in an embodiment, to a process for the deposition on a polymer substrate of a decorative coating comprising a boron doped silicon oxide protective toplayer, wherein the protective toplayer comprises Si, O, B, and OH groups and wherein the boron content is comprised between 4 and 12 atomic %, comprising:
a. providing a polymer substrate,
b. providing a plasma source, of linear hollow-cathode type, which plasma source has a length, comprising at least one pair of hollow-cathode plasma generating electrodes connected to an AC, DC or pulsed DC generator power source, for the deposition of said protective toplayer on the substrate,
c. injecting a plasma generating reactive gas comprising oxygen in the plasma source's electrodes at a flow rate of between 125 and 750 sccm per linear meter of plasma source length,
d. applying an electrical power to the plasma source of between 10 and 50 kW per linear meter of plasma source length so as to generate a plasma, and,
e. injecting a precursor gas comprising boron, silicon and hydrogen at a flow rate of between 500 and 2500 sccm per linear meter of plasma source length, the precursor gas being injected into the plasma at least in between the electrodes of each electrode pair of the plasma source, depositing the protective toplayer on the polymer substrate by exposing the substrate to the plasma of the plasma source.

Standard cubic centimeters per minute, “sccm”, is a unit of flow measurement indicating cubic centimeters per minute (cm³/min) in standard conditions for temperature and pressure of a given fluid. These standard conditions are for the present invention fixed at a temperature of 0° C. (273.15 K) and a pressure of 1.01 bar.

According to an embodiment of the present invention, the multilayer coating further comprises one or more layers for example deposited by magnetron sputtering and/or PECVD. Optionally additional coatings may be deposited by the same technologies for example after the deposition of the protective toplayer. Thereby multilayer coatings as described hereinabove, comprising a protective boron doped silicon oxide layer, may be formed.

Stage b) of the process of the present invention requires a low-pressure PECVD plasma source, which pressure is preferably between 0.13 and 66.66 Pa (0.001 and 0.5 Torr), preferably between 0.13 and 4.00 Pa and more preferably between 0.40 and 2.67 Pa, which device is provided with a linear plasma source of hollow-cathode type, comprising at least one electrode pair, connected to an AC or pulsed DC generator, the frequencies of which are usually between 5 and 150 kHz, preferably between 5 and 100 kHz, or to a DC generator. The pressure is maintained by vacuum pumps.

A PECVD device example is described below. The PECVD source is connected to or provided in a vacuum chamber. This vacuum chamber is arranged so that it makes it possible to have, next to one another, several PECVD devices or else other deposition sources having different deposition forms, in the same vacuum chamber or in separate, connected vacuum chambers. In certain applications, these other deposition sources, which make possible different deposition forms, are flat or rotating cathodes for magnetron sputtering deposition. The deposition sources are chosen and combined in a coater so as to provide the deposition process of a multilayer coating comprising the protective toplayer of the present invention, in particular on glass substrates having dimensions up to at least 3.2×6 m².

The vacuum chamber may be part of a horizontal coater or of a vertical coater and may further comprise a transfer chamber.

Linear plasma sources are particularly useful for depositing uniform layers on large substrates in a dynamic or continuous coating process. They are placed perpendicularly to the travelling direction of the substrates so as to span in their lengthwise direction over the width of the substrates. An advantage of linear plasma sources is their scalability. Their length may thus be adapted to span substrates of different widths, the applied power and the gas flow and precursor flow rates being adapted proportionally to the length. The width of linear plasma sources extends parallel to the travelling direction of the substrate. Showerhead type plasma sources or point plasma sources are in particular less suitable for large substrates extending over more than 1×1 m² as coating of such large substrates requires complicated arrangements such as arrays of multiple sources for example and uniformity is difficult to achieve.

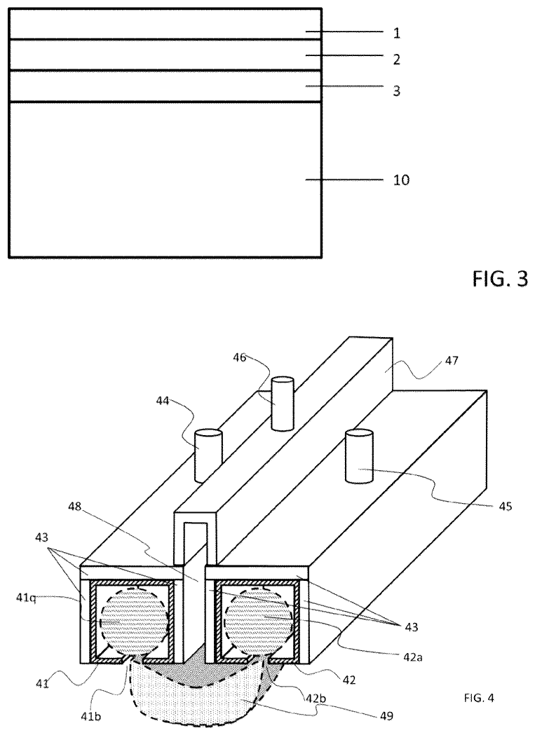

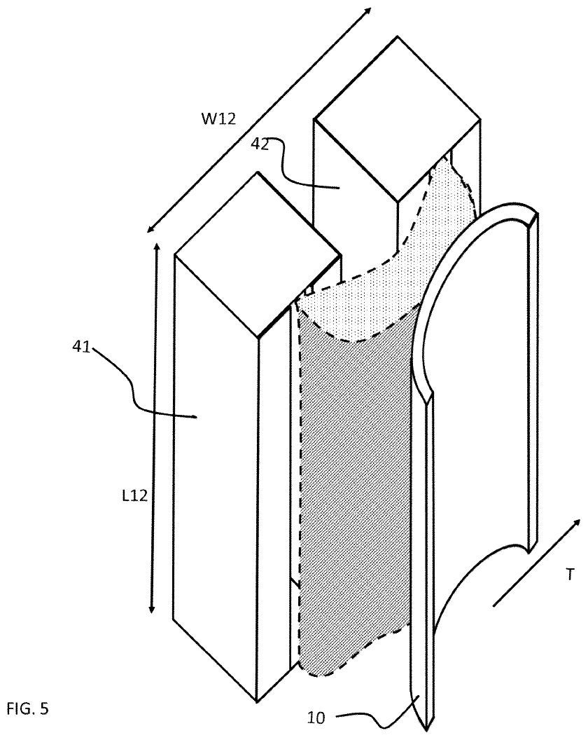

“Plasma source of hollow cathode type,” is taken to mean a plasma or ion source comprising one or more electrodes configured to produce hollow cathode discharges. One example of a hollow cathode plasma source is described in U.S. Pat. No. 8,652,586, incorporated herein by reference in its entirety. FIG. 4 shows a plasma source of hollow cathode type that may be used in the present invention. The plasma source comprises at least one pair of hollow cathode electrodes (41, 42), arranged in parallel and connected via an AC power source (not shown). Electrically insulating material (43) is disposed around the hollow cathode electrodes. The plasma generating gas is supplied via the inlets (44) and (45). The precursor gas is supplied via the precursor gas inlet (46) and led through manifold (47) and precursor injection slot (48) in the dark space between the electrodes, into the plasma curtain (49). The AC power source supplies a varying or alternating bipolar voltage to the two electrodes. The AC power supply initially drives the first electrode to a negative voltage, allowing plasma formation, while the second electrode is driven to a positive voltage in order to serve as an anode for the voltage application circuit. This then drives the first electrode to a positive voltage and reverses the roles of cathode and anode. As one of the electrodes is driven negative, a discharge (41a, 42a) forms within the corresponding cavity. The other electrode then forms an anode, causing electrons to escape the plasma through the outlet (41b, 42b) and travel to the anodic side, thereby completing an electric circuit. A linear plasma having a curtain shape (49) is thus formed in the region between the first and the second electrodes above the substrate as shown on FIG. 5. This method of driving hollow cathodes with AC power contributes formation of a uniform linear plasma that spans across the substrate (10), the length (L12) of the plasma source being perpendicular to the travelling direction (T) of the substrate and the width (W12) of the plasma source being parallel to the travelling direction (T) of the substrate.

In linear hollow cathode type plasma sources, it is possible to create a uniform plasma without relying on closed circuit electron drift. “Closed circuit electron drift” is taken to mean an electron current caused by crossed electric and magnetic fields. In many conventional plasma forming devices, the closed circuit electron drift forms a closed circulating path or “racetrack” of electron flow.

“AC power” is taken to mean electric power from an alternating source wherein the voltage is changing at some frequency in a manner that is sinusoidal, square wave, pulsed or some other waveform. Voltage variations are often from negative to positive, i.e. with respect to ground. When in bipolar form, power output delivered by two leads is generally about 180° out of phase.

“Electrodes” provide free electrons during the generation of a plasma, for example, while they are connected to a power supply providing a voltage. The electron-emitting surfaces of a hollow cathode are considered, in combination, to be one electrode. Electrodes can be made from materials well-known to those of skill in the art, such as steel, stainless steel, copper, or aluminum. However, these materials must be carefully selected for each plasma-enhanced process, as different gasses may require different electrode materials to ignite and maintain a plasma during operation. It is also possible to improve the performance and/or durability of the electrodes by providing them with a coating.

For any plasma source of the present invention, the power density of the plasma is defined as being the power dissipated in the plasma generated at the electrode(s), with reference to the size of the plasma. In a linear hollow-cathode type plasma source, the “power density of the plasma” can be defined as the total power applied to the source, divided by the total length of the plasma source.

The “linear meter of plasma length”, refers to the length of the plasma which is defined as the distance between the ends of the plasma generated by a pair of electrodes, in the direction transversal to the travelling direction of the substrate to be coated. When the plasma source comprises more than one pair of electrodes, the length of the plasma is defined as the sum of the distances between the ends of the plasmas generated by each pair of electrodes, in the direction transversal to the travelling direction of the substrate to be coated. As may be well understood by any person skilled in the art, these linear hollow cathode plasma sources are scalable in that their length may be adapted so as to span the width of the substrate to be treated. Plasma source lengths may for example be of several meters. It makes sense therefore to express flow rates and applied power in units dependent on the overall length of the plasma source, as for example doubling the length of a plasma source obviously requires doubling the applied power and flow rates.

As used herein, the following terms have the following meanings: “A”, “an”, and “the” as used herein refers to both singular and plural referents unless the context clearly dictates otherwise. By way of example, “a chamber” refers to one or more than one chamber.

“Comprise,” “comprising,” and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited components, features, elements, members or steps, known in the art or disclosed therein.

The recitation of numerical ranges by endpoints includes all numbers and fractions subsumed within that range, as well as the recited endpoints.

The pairs of electrodes, forming cavities in which the plasma discharge takes place, are each connected to pipes for the introduction of a reactive plasma generating gas and provided with openings from where the ionized gas, i.e. the plasma, is expelled.

The frequency of the power source connected to the electrodes may be between 5 and 150 kHz, preferably between 5 and 100 kHz.

The at least one pair of electrodes of the linear plasma source is may have a length of between 250 mm and 4000 mm and between 100 and 800 mm in width.

Such values have the advantage of ensuring an amount of reactive gas which is sufficiently greater than that of the precursors, making it possible to control and/or avoid the incorporation of carbon in the layer. Applied power, reactive gas and precursor flow rates are adapted proportionally to the length of the linear plasma source.

The power source provides a power preferably between 5 kW per linear meter of plasma source length and 50 kW, advantageously between 10 and 35 kW per linear meter of plasma source length. Below this power of 5 kW per linear meter of plasma source, presence of carbon in the protective toplayer is observed and above 50 kW per linear meter of plasma source, arc formation may be observed which is detrimental to the lifetime of the plasma source and/or the quality of the decorative coating.

The reactive gas comprises oxygen or on oxygen-comprising derivatives, the latter preferably being chosen from the group consisting of ozone, hydrogen peroxide, water and CO₂. According to embodiments, the reactive gas can in addition advantageously include an inert gas, such as helium, nitrogen, argon, neon or krypton, in order to promote the chemical dissociation of the precursors and to control the ion bombardment by the source. If present, the percentage of inert gas in the reactive gas is comprised between 2% and 50% by volume, preferably between 3% and 10% by volume, more preferably between 4% and 7% by volume. This choice makes it possible to control the coverage of the layer obtained

The reactive gas is preferably O₂ or an O₂—Ar mixture.

In an embodiment of the present invention, the reactive gas flow rate is comprised between 2000 and 5000 sccm per linear meter of plasma source length.

The precursor gas comprising boron, silicon and hydrogen is injected uniformly along the length plasma source into the plasma. The precursor may for example be injected in between the electrodes of an electrode pair and/or, if there are more than one electrode pairs, between adjacent electrode pairs. This precursor gas is activated by this plasma. The substrate is taken close to the source and a thin layer is deposited on the substrate from the activated gas.

The precursor gas flow rate is preferably between 125 and 750 sccm per linear meter of plasma source length. Generally, if the precursor gas comprises a mixture of precursors, then the precursor gas flow rate is the sum of the flow rates of the precursors of the mixture.

The distance between the substrate surface and the opening of the plasma source, via which the plasma is emitted out of the source, is preferably at least 2.0 to 20 cm, more preferably at least 4 to 15 cm.

Preferably, the ratio of the reactive gas flow rate to the precursor gas flow rate is at least 3, advantageously between 3 and 50.

The precursor gas comprises silicon, boron and hydrogen and may in particular further comprise carbon and/or oxygen.

The precursor gas may comprise a single precursor, meaning a single precursor or may comprise a mixture of precursors, meaning a mixture of different precursor of different composition. The ratio of precursors is adapted to set the boron doping at the desired level, in particular for boron content from 4 to 12 at % of B in the boron doped silicon oxide layer.

According to an embodiment of the present invention, the precursor gas comprises at least one precursor comprising Si, at least one precursor comprising B and/or at least one precursor comprising Si and B. Any of the precursors in the precursor gas may further comprise hydrogen. Any of the precursors in the precursor gas may further comprise carbon. Any of the precursors may further comprise oxygen.

The temperature to which the substrate may be brought during deposition of the protective toplayer is between 20° C. and 60° C. depending on the residence time of the substrate in the plasma, for instance depending on the speed of displacement of the substrate beneath the plasma source.

In an embodiment of the present invention, a precursor comprising silicon is free of boron, that is does not comprise boron, and is preferably of the formula (I), (II), (III), (IV) or (V).

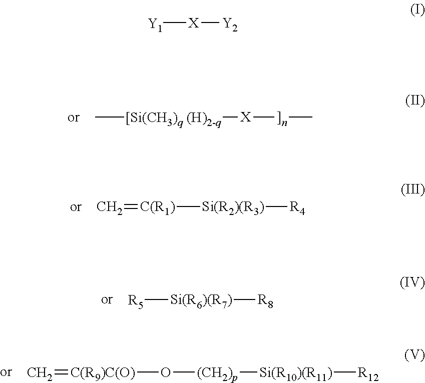

wherein for Formula (I) X is O or NH, Y₁ is —Si(Y₃)(Y₄)Y₅ and Y₂ is Si(Y_{3′})(Y_{4′})Y_{5′} wherein Y₃, Y₄, Y₅, Y_{3′}, Y_{4′}, and Y_{5′} are each independently H or an alkyl group of up to 10 carbon atoms; wherein at most one of Y₃, Y₄ and Y₅ is hydrogen, at most one of Y_{3′}, Y_{4′} and Y_{5′} is hydrogen; and the total number of carbon atoms is not more than 20.
wherein Formula (II) is cyclic where n is 2 to 10, wherein q is 0 to 2 and wherein the total number of carbon atoms is not more than 20.
wherein for Formula (III) R₁ is H or an alkyl group, e.g. —CH₃, and wherein R₁, R₂ and R₃ are each independently H, an alkyl group of up to 10 carbon atoms or an alkoxy group —O—Z, wherein Z is preferably —CₜH₂ₜ₊₁, wherein t is 1 to 10.
wherein for Formula (IV) R₅ is H or an alkyl group, e.g. —CH₃, and wherein R₆, R₇ and R₈ are each independently H, an alkyl group of up to 10 carbon atoms or an alkoxy group —O—Z, wherein Z is preferably —CₜH₂t+₁, wherein t is 1 to 10.
wherein for Formula (V) R₉ is H or an alkyl group, e.g. —CH₃, wherein p is from 0 to 10, and wherein R₁₀, R₁₁ and R₁₂ are each independently H, an alkyl group of up to 10 carbon atoms or an alkoxy group —O—Z, wherein Z is preferably —CₜH₂ₜ₊₁, wherein t is 1 to 10.

The alkyl groups may be straight or branched-chain but straight groups are preferred. Such alkyl groups are aptly methyl or ethyl groups of which methyl is preferred. Aptly all of Y₃, Y₄, Y₅, Y_{3′}, Y_{4′} or Y_{5′} are alkyl groups.

The alkoxy groups may be straight, branched-chain or cyclic but straight groups are preferred. Such alkoxy groups are aptly methoxy or ethoxy groups.

The silicon-comprising precursor of Formula I may be one containing six methyl groups. Aptly the silicon-comprising precursor of Formula I is hexamethyldisiloxane (HMDSO), hexamethyldisilazane or tetramethyldisiloxane (TMDSO).

The silicon-comprising precursor of Formula II may be one wherein n is 3, or n is 4, or n is 5, or n is 6. Aptly the silicon-comprising precursor of Formula II is octamethylcyclotetrasiloxane. Aptly the silicon-comprising precursor of Formula II is hexamethylcyclotrisilazane.

The silicon-comprising precursor of Formula V may be one wherein p is 2 and wherein each of R₁₀, R₁₁ and R₁₂ are an alkoxy group, e.g. methoxy.

Aptly the silicon-comprising precursor of Formula V is 3-(trimethoxysilyl)propyl methacrylate. Aptly the silicon-comprising precursor of Formula V is 3-(trimethoxysilyl)propyl acrylate.

In an embodiment of the present invention, a precursor comprising boron is free of silicon, meaning is not comprising Si, and is preferably of the formula (VI):

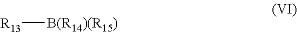

wherein R₁₃, R₁₄ and R₁₅ are each independently H, an alkyl group of up to 10 carbon atoms or an alkoxy group —O—Z, wherein Z is preferably —CₜH₂ₜ₊₁, wherein t is 1 to 10.

The alkyl groups may be straight or branched-chain but straight groups are preferred. Such alkyl groups are aptly methyl or ethyl groups of which methyl is preferred.

The alkoxy groups may be straight, branched-chain or cyclic but straight groups are preferred. Such alkoxy groups are aptly methoxy, ethoxy, or isopropoxy groups.

In an embodiment of the present invention, for Formula (VI), R₁₃, R₁₄ and R₁₅ are all ethoxy or R₁₃, R₁₄ and R₁₅ are all isopropoxy groups.

In an embodiment of the present invention, a boron and silicon comprising precursor is of the formula (VII):

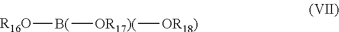

Wherein R₁₆, R₁₇, and R₁₈ are all independently organosilyl groups, in particular trialkylsilyl groups, an alkyl group of up to 10 carbon atoms. Aptly such trialkylgroups are trimethylsilyl, triethylsilyl or diethyl(methyl)silyl groups. Aptly such a boron and silicon precursors is tris(trimethylsilyl)borate (TTMSB).

Preferably, any precursor of boron, silicon and/or both silicon and boron is transported to the plasma source without the use of a carrier gas. However, in some embodiments, an additional gas may be used as carrier gas to introduce a precursor into the plasma chamber.

Preferably any precursor is supplied as a liquid which is subsequently vaporized and transported to the plasma source in its vaporized form.

Preferably any vaporized precursor is transported to the plasma chamber without the use of a carrier gas. Alternatively, if necessary, the liquid precursor supply system uses a carrier gas to transport the vaporized precursor into the plasma chamber.

Preferably, when a carrier gas is used, the carrier gas is selected from N₂, He or Ar, and/or any mixture of these gases. In one preferred process, a single carrier gas is used. This is most preferably He or Ar.

Preferably, when a carrier gas is used, the amount of carrier gas is about 5% to about 1500% carrier gas based on the total flow of all silicon and boron precursors, preferably about 10% to about 1000% additional gas, more preferably 20% to 750%, for example 25% to 500%, such as 500, 450, 400, 350, 300, 250, 200, 175, 150, 125, 100, 90, 80, 75, 70, 60, 50, 40, 35, 30, or 25% carrier gas.

Any precursors may be gaseous at room temperature and pressure, or may be vaporized liquids.

The flow rates of the different precursors below are necessary in order to obtain high dynamic deposition rates, in the order of 20 to 500 nm·m/min. Generally higher precursor flow rates require higher power applied to the plasma source.

In an embodiment of the present invention the total flow rate of the silicon-comprising precursors is comprised between 10 and 500 sccm (standard cubic centimeters per minute) per linear meter of plasma length, preferably between 50 and 500 sccm or between 50 and 400 sccm per linear meter of plasma length.

The unit «nm·m/min» is used in the present application to express the deposition rate. This unit is a combination of SI units which is typically used to characterize deposition rates of dynamic or continuous coating processes, that is, processes wherein the substrate moves continuously through a deposition device. Deposition rates for such deposition devices are commonly called «dynamic deposition rates» and are used to express the deposition rate of the decorative coating equipment itself, independently of the speed at which the substrate moves through the deposition equipment.

In an embodiment of the present invention the total flow rate of the boron-comprising precursors is comprised between 10 and 500 sccm (standard cubic centimeters per minute) per linear meter of plasma length, preferably between 50 and 500 sccm or between 50 and 400 sccm per linear meter of plasma length.

In an embodiment of the present invention the total flow rate of the silicon and boron-comprising precursors is between 10 and 750 sccm (standard cubic centimeters per minute) per linear meter of plasma length, preferably between 50 and 750 sccm or between 50 and 600 sccm per linear meter of plasma length.

As the case may be, stage c) may additionally comprise applying to the substrate an additional precursor, for example in order to include a specific additional oxide such as titanium oxide or zirconium oxide, to further improve mechanical and/or chemical durability and/or to increase the refractive index of the boron doped silicon oxide protective toplayer.

According to an embodiment of the present invention the boron doped silicon oxide protective toplayer comprises at least 80% by weight of silicon oxide SiO₂.

According to an embodiment of the present invention the boron doped silicon oxide protective toplayer comprises up to 15% by weight of titanium oxide, zirconium oxide or a mixture thereof.

The present invention is defined in the appended independent claims. Preferred embodiments are defined in the dependent claims.

It is noted that the invention relates to all possible combinations of features recited in the claims or in the embodiments hereinabove.

In an embodiment of the present invention, the decorative coating comprises a metal coating in between the substrate and the protective toplayer. Preferably a metal coating is deposited on the polymer substrate before depositing the protective toplayer. The metal coating may comprise one or more metal layers.

Deposition of the metal coating is preferably performed using a physical vapor deposition process, advantageously using a conventional magnetron sputtering processes, well known in the art. Representative descriptions of sputter-depositing processes and equipment may be found in for example U.S. Pat. Nos. 4,204,942A, 4,948,087A, 5,589,280A, US20110275262A1, KR20120026936A, and EP0546470A1 which are incorporated by reference. In other embodiments of the present invention the deposition of the one or more thin metal layers is performed using evaporation, such as thermal evaporation or e-beam evaporation. The material deposited by any physical vapor deposition technique may advantageously be selected among Ag, Cu, Al, Cr, Ti, or silicon, or metal alloys as NiCr-alloys or NiCrW alloys.

In an embodiment of the present invention, the thickness of the metal coating is advantageously comprised between 20 nm and 300 nm in order to achieve de desired level of opaqueness and level of reflectance desirable for certain applications, in particular to achieve a metal-like appearance, advantageously between 30 nm and 150 nm, more advantageously between 40 nm and 120 nm.

In a preferred embodiment of the present invention the metal coating comprises one reflecting layer. The reflecting layer is the topmost layer in the metal coating, i.e. is located furthest away from the substrate surface. The reflecting layer is thus visible through any following layers, in particular the protective toplayer, and responsible to a large degree for the metallic aspect provided to the substrate by the metal coating. In an advantageous embodiment of the present invention the reflecting layer is an aluminum layer. The reflecting layer may have a thickness comprised between 10 and 25 nm and may in particular be the thickest layer in the metal coating.

In certain embodiments of the present invention, the targets used for magnetron sputtering may be circular target or linear targets, linear targets being particularly useful in continuous coating processes. The targets used may be metallic targets, comprising for example metals chosen among Ag, Cu, Al, Cr, Ti, or silicon based targets, or metal alloy targets comprising for example NiCr-alloys or NiCrW alloys.

In an advantageous embodiment, the metal coating comprises, in addition to the reflecting layer, a metal base layer in direct contact with the polymer substrate. The metal base layer may improve the adhesion of the metal coating to the polymer substrate. The material of the metal base layer is different than the material of the reflecting layer, and may be selected from NiCr. The NiCr metal base layer may consist of an alloy of Ni and Cr in a Ni/Cr weight ratio of between 99/1 and 50/50, preferentially 80/20. The metal base layer is advantageously in direct contact with the metal reflecting layer. The inventors found that such a metal base layer further increases mechanical and chemical resistance of the decorative coating.

In an alternate embodiment, the decorative coating comprises a carbon adhesion layer in between the metal coating and the polymer substrate. The carbon adhesion layer may be in direct contact with the metal coating. The carbon adhesion layer may be in direct contact with the polymer substrate. The carbon adhesion layer may have a thickness comprised between 4 and 10 nm. FIG. 3 shows a polymer substrate (10) wherein the carbon adhesion layer (3) is in direct contact with the substrate, the metal coating (2) is in direct contact with the adhesion layer and the protective toplayer (1) is in direct contact with the metal coating (2).

Depositing a carbon adhesion layer on the polymer substrate, using an additional plasma source, of linear hollow-cathode type may comprise:
a. providing an additional plasma source, of linear hollow-cathode type, comprising at least one pair of hollow-cathode plasma generating electrodes connected to an AC, DC or pulsed DC generator, for the deposition of said carbon adhesion layer on said polymer substrate;
b. injecting a plasma generating gas, preferably selected among N₂, He, Ar or among a mixture of two or more of these gases, in the additional plasma source's electrodes at a flow rate of between 1000 and 5000 sccm, preferably between 1500 and 4500 sccm, more preferably between 2000 and 4000 sccm per linear meter of the additional plasma source length;
c. applying an electrical power to the additional plasma source, of between 2 kW and 20 kW per linear meter of the additional plasma source length;
d. injecting a gaseous precursor of carbon, for example selected among CH₄, C₂H₄, C₂H₂, C₃H₈, C₄H₁₀, preferably CH₄, at a flow rate of between 50 and 600 sccm, preferably between 100 and 500 sccm, more preferably between 200 and 400 sccm per linear meter of the additional plasma source length, the gaseous precursor being preferably injected into the plasma in at least between the electrodes of each electrode pair of the additional plasma source;
e. exposing the substrate to the plasma of the additional plasma source, thereby depositing a carbon adhesion layer comprising a layer which is based on carbon on the activated surface of the substrate.

The inventors have found that, the carbon adhesion layer improves the chemical resistance of the decorative.

In certain embodiments, the additional plasma source is connected to a generator providing an AC or pulsed DC current at a frequency comprised between 5 and 150 kHz, alternately between 5 and 100 kHz.

In certain embodiments of the present invention the distance between the substrate surface and the outlets of the additional plasma source is comprised between 50 and 150 mm, advantageously between 60 and 120 mm, more advantageously between 80 and 100 mm.

In certain embodiments of the present invention, carbon adhesion layer deposition is performed at a pressure comprised between 0.005 and 0.050 Torr, more advantageously comprised between 0.010 and 0.040 Torr, even more advantageously between 0.020 and 0.030 Torr.

In certain embodiments of the present invention, the hybridization ratio sp3/sp2 of the carbon adhesion layer is comprised between 0.6 and 0.8.

In an advantageous embodiment of the present invention a barrier layer, for example of silicon nitride is deposited directly on the topmost metal layer so as to protect the metal layer from oxidation upon depositing the protective toplayer. The barrier layer may be in direct contact with the protective toplayer.

In certain embodiments of the present invention, the magnetron sputtering deposition of the metal layers may be performed applying a power comprised between 1 kW and 20 kW per linear meter of target.

In certain embodiments of the present invention the plasma generating gas used for physical vapor deposition of metal layers is advantageously Argon.

In certain embodiments of the present invention, physical vapor deposition is advantageously performed at a pressure comprised between 0.002 Torr and 0.050 Torr, more advantageously comprised between 0.003 Torr and 0.020 Torr, even more advantageously between 0.004 Torr and 0.010 Torr.

In certain embodiments deposition of the metal layers by evaporation is performed using ingots of the same materials as the targets mentioned hereinabove for magnetron sputtering.

The metal coating provides mainly the decorative metallic aspect of the resulting coated substrate. The metallic aspect may be enhanced by the protective toplayer.

In certain embodiments of the present invention the polymer substrate may be homogeneous sheets of polymer, but other shapes, for example three dimensional shapes, are also possible.

In certain embodiments of the present invention, a polymer substrate may comprise acrylic polymers, polymethylmethacrylate (PMMA) and its copolymers, CR-39 or allyl diglycol carbonate (ADC), polycarbonate, poly propylene (PP), biaxially oriented polypropylene (BOPP), Polyethylene (PE), Polyvinylchloride (PVC) polyethylene terephthalate (PET), polystyrene, cyclic olefin co-polymers (COC's) and polyethylene terephthalate glycol (PETG), and combinations of the foregoing. Polymer substrates of the present invention may comprise thermoplastic elastomers (TPE), sometimes referred to as thermoplastic rubbers, which are a class of copolymers or a physical mix of polymers, usually a plastic and a rubber, that consist of materials with both thermoplastic and elastomeric properties. In particular the polymer substrates may comprise Styrenic block copolymers, TPS (TPE-s), Thermoplastic polyolefinelastomers, TPO (TPE-o), Thermoplastic Vulcanizates, TPV (TPE-v or TPV), Thermoplastic polyurethanes, TPU (TPU), Thermoplastic copolyester, TPC (TPE-E), Thermoplastic polyamides, TPA (TPE-A).

In certain embodiments of the present invention a polymer substrate may be a thin polymer film, having a thickness comprised between 5 μm and 300 μm, alternately between 10 μm and 250 μm, alternately between 20 μm and 200 μm, alternately between 25 μm and 150 μm. These polymer thin films may be processed in a roll-to-roll manner.

For the examples below, polymer substrates of a blend of polycarbonate and (PC) and Acrylonitrile butadiene styrene (ABS) and of ABS only were used. Both substrates led to comparable results. These substrates have a matte aspect, the Gloss values of these uncoated substrates is low. Deposition of SiO₂ on these substrates was found to increase their gloss.

The following examples 1 and 3 are comparative examples, while examples 2 and 4 are according to the present invention.

For example 1, a layer of SiO₂ was deposited by magnetron sputtering from a silicon target in an Ar/O₂ atmosphere. The thickness of the SiO₂ layer was 130 nm.

For example 2, a layer of boron doped silicon oxide (SiO₂:B) was deposited by hollow cathode PECVD, using O₂ reactive gas and a mixture of TTMSB and TEB as precursor gas. The thickness of the SiO₂ layer was 130 nm.

For example 3, a metal coating consisting of a first adhesion metal layer of NiCr alloy of 4 nm was deposited on the polymer substrate, followed by a reflecting metal layer of aluminum of 17 nm thickness. A barrier layer of Si₃N₄ was deposited on the metal coating. Both metal layers were deposited by magnetron sputtering in an Ar atmosphere from the corresponding metallic targets. The Si₃N₄ layer of 9 to 10 nm was deposited by magnetron sputtering from a Si target in an Ar/N₂ atmosphere. Then a layer of SiO₂ identical to the layer of example 1 was deposited.

For example 4, a metal coating consisting of a first adhesion metal layer of NiCr alloy of 4 nm was deposited on the polymer substrate, followed by a reflecting metal layer of aluminum of 17 nm thickness. A barrier layer of Si₃N₄ was deposited on the metal coating. Both metal layers were deposited by magnetron sputtering in an Ar atmosphere from the corresponding metallic targets. The Si₃N₄ layer of 9 to 10 nm was deposited by magnetron sputtering from a Si target in an Ar/N₂ atmosphere. Then a layer of SiO₂:B identical to the layer of example 2 was deposited.

For example 5, a metal coating consisting of a first adhesion metal layer of NiCr alloy of 4 nm was deposited on the polymer substrate, followed by a reflecting metal layer of aluminum of 17 nm thickness. A barrier layer of Si₃N₄ was deposited on the metal coating. Both metal layers were deposited by magnetron sputtering in an Ar atmosphere from the corresponding metallic targets. The Si₃N₄ layer of 9 to 10 nm was deposited by magnetron sputtering from a Si target in an Ar/N₂ atmosphere. Then a polyurethane based lacquer layer was spray coated over the sputter deposited layers.

For example 6, a metal coating consisting of a first adhesion carbon layer of 10 nm was deposited on the polymer substrate by hollow cathode PECVD, followed by a reflecting metal layer of aluminum of 17 nm thickness. A barrier layer of Si₃N₄ was deposited on the metal coating. The metal layer was deposited by magnetron sputtering in an Ar atmosphere from an aluminum metallic target. The Si₃N₄ layer of 9 to 10 nm was deposited by magnetron sputtering from a Si target in an Ar/N₂ atmosphere. Then a 130 nm thick layer of undoped SiO₂ was deposited was deposited by hollow cathode PECVD, using O₂ reactive gas and TMDSO (teramethyldisiloxane).

The crockmeter test is a dry rub test performed as described in standard ISO11998:1998 with a cylindrical finger having a diameter of 15 mm and a 9 μm, 1200 grain, sandpaper pad. For the present invention, 10 double strokes corresponding to 20 cycles are performed on a dry sample, without addition of any liquid. The total weight on the abrasive pad is 900 g.

Gloss measurements were performed according to ASTM standard D523-2014 at a specific angle of 60°, using a certified black glass standard with a gloss at 60° of 96.0.

The relative reduction of gloss expressed as percentage of initial gloss was determined after the crockmeter test.

For examples 1, and 5 gloss was reduced by 30 to 40%. For examples 2, and 4 the gloss was reduced by 3% and 1 to 2% respectively. For example 6 the gloss was reduced by 3 to 4%.

Examples 2, 4 and 6 were submitted to a chemical durability test: the copper accelerated acetic acid salt spray test (CASS) according to standard ISO 9227-2006. In Example 6, coating delamination occurred already after 24h of testing, while for examples 2 and 4, after 48h some reduction of gloss was observed, but the level of gloss reduction was less than 30%. The boron doped SiO₂ thus shows markedly better resistance to chemical attack.

1. A polymer substrate bearing a decorative coating comprising a protective toplayer of boron doped silicon oxide, wherein the boron doped silicon oxide comprises Si, O, B, and H, wherein the boron content is comprised between 4 and 12 atomic % and OH groups.

2. The polymer substrate according to claim 1 wherein the protective toplayer comprises at least 80 weight % of SiO₂.

3. The polymer substrate according to claim 1, wherein the O/Si atomic ratio of the protective toplayer is comprised between 1.9 and 2.6.

4. The polymer substrate according to claim 1, wherein the protective toplayer is free of carbon.

5. The polymer substrate according to claim 1, wherein the protective toplayer has a thickness of at least 80 nm and/or at most 400 nm.

6. The polymer substrate according to claim 1, wherein the protective toplayer is in direct contact with the polymer substrate.

7. The polymer substrate according to claim 1, wherein the decorative coating further comprises a metal coating comprising one or more metal layers between the substrate and the protective toplayer.

8. The polymer substrate according to claim 7, wherein the metal coating has a thickness comprised between 20 nm and 300 nm.

9. The polymer substrate according to claim 7, wherein the metal coating comprises a reflecting metal layer of a metal chosen from Ag, Cu, Al, Cr, Zr, Ti, Si, or NiCrW alloys and optionally a metal base layer of NiCr in direct contact with the substrate and the reflecting metal layer.

10. The polymer substrate according to claim 7, wherein the decorative coating further comprises a carbon adhesion layer between the substrate and the metal coating.

11. The polymer substrate according to claim 7, wherein the decorative coating comprises in direct contact with the metal coating and the protective toplayer a barrier layer of Si₃N₄.

12. A process for the deposition on a polymer substrate of a decorative coating comprising a boron doped silicon oxide protective toplayer, wherein the protective toplayer comprises Si, O, B, and OH groups and wherein the boron content is comprised between 4 and 12 atomic %, comprising:
a. providing a polymer substrate,
b. providing a plasma source, of linear hollow-cathode type, which plasma source has a length, comprising at least one pair of hollow-cathode plasma generating electrodes connected to an AC, DC or pulsed DC generator power source, for the deposition of said protective toplayer on the substrate,
c. injecting a plasma generating reactive gas comprising oxygen in the plasma source's electrodes at a flow rate of between 125 and 750 sccm per linear meter of plasma source length;
d. applying an electrical power to the plasma source of between 10 and 50 kW per linear meter of plasma source length so as to generate a plasma, and,
e. injecting a precursor gas comprising boron, silicon and hydrogen at a flow rate of between 500 and 2500 sccm per linear meter of plasma source length, the precursor gas being injected into the plasma at least in between the electrodes of each electrode pair of the plasma source, depositing the protective toplayer on the polymer substrate by exposing the substrate to the plasma of the plasma source.

13. The process according to claim 12, wherein the precursor gas comprises at least one precursor comprising Si, at least one precursor comprising B and/or at least one precursor comprising Si and B.

14. The process according to claim 12, wherein the reactive gas is O₂ or a O₂—Ar mixture.

15. The process according to claim 12, wherein the reactive gas flow rate is comprised between 200 and 500 sccm per linear meter of plasma source length.

16. The process according to claim 12, wherein the precursor gas comprises at least one precursor selected from a silicon comprising precursor, a boron-comprising precursor and/or a silicon- and boron-comprising precursor and wherein the total flow rate of each precursor is comprised between 10 and 500 sccm.
